(19) United States
(12) Patent Application Publication
(10) Pub. No.: US 2026/0059727 A1
(43) Pub. Date: Feb. 26, 2026

(54) HEAT EXCHANGE APPARATUS, INVERTER COOLING SYSTEM AND CONVERTER COOLING SYSTEM

(71) Applicant: ZHEJIANG YINLUN MACHINERY CO., LTD., Taizhou (CN)

(72) Inventors: Guodong LU, Taizhou (CN); Zhonghua CHAI, Taizhou (CN); Junbin XI, Taizhou (CN); Tingting SHI, Taizhou (CN)

(21) Appl. No.: 19/376,664

(22) Filed: Oct. 31, 2025

Related U.S. Application Data
(63) Continuation of application No. PCT/CN2024/107633, filed on Jul. 25, 2024.

(30) Foreign Application Priority Data
May 11, 2024 (CN) 202410579550.7

(51) Int. Cl. H05K 7/20

(52) U.S. Cl. CPC H05K 7/20936

(57) ABSTRACT

A heat exchange apparatus, an inverter cooling system, and a converter cooling system. The heat exchange apparatus includes an evaporation section, a condensation section, a vapor pipe, a return pipe, a gas-collecting hood and a plurality of gas outlet pipes. The vapor pipe is in communication with the evaporation section and the condensation section. The vapor pipe protrudes from a second return wall defined by a bottom wall of the condensation section. The return pipe is in communication with the evaporation section and the condensation section. The return pipe does not protrude outward from the second return wall. The gas-collecting hood is disposed on the condensation section and is provided with a gas-collecting groove, the gas-collecting groove is provided with an opening towards the second return wall. The plurality of gas outlet pipes protrude from a first return wall defined by a bottom of the gas-collecting groove.

### CROSS-REFERENCE TO RELATED APPLICATIONS

This application is a continuation of international patent application No. PCT/CN2024/107633, filed on Jul. 25, 2024, which itself claims priority to Chinese patent application No. 202410579550.7, filed on May 11, 2024, and titled “HEAT EXCHANGE APPARATUS, INVERTER COOLING SYSTEM AND CONVERTER COOLING SYSTEM”. The contents of the above identified applications are hereby incorporated herein in their entireties by reference.

### TECHNICAL FIELD

The present disclosure relates to the field of heat pipe heat exchange technology, and in particular, to a heat exchange apparatus, an inverter cooling system and a converter cooling system.

### BACKGROUND

In apparatuses such as photovoltaic inverters and photovoltaic converters, power elements (including but not limited to insulated gate bipolar transistors (IGBT), chips, motors, and so on) inside the apparatuses are required to be cooled. At present, a heat pipe heat exchanger has a relatively great heat exchange effect, and the heat pipe heat exchanger generally adopts an annular loop. Specifically, in the heat pipe heat exchanger, after a working medium in an evaporation section being heated and gasified, the working medium vapor is evaporated and conveyed to a condensation section via a plurality of pipelines, is condensed into a liquid working medium after being regularly cooled, and returns to the evaporation section via a liquid return pipe, so that whole circulation forms an annular loop.

At present, the heat pipe heat exchanger has the following problems: in order to make a layout of the heat pipe heat exchanger more compact, the evaporation section and the condensation section are disposed in the same plane, and the rising gaseous working medium and the falling liquid working medium share the same channel, so that vapor rising in the evaporation section may interfere with condensate returning from the condensation section, thereby affecting heat exchange efficiency of the heat pipe heat exchanger.

### SUMMARY

Based on the above problem, it is required to provide a heat exchange apparatus, an inverter cooling system, and a converter cooling system to solve a problem of interference between the rising vapor and the returning condensate in related heat pipe heat exchangers.

The heat exchange apparatus of the present disclosure includes an evaporation section, a condensation section, a vapor pipe, a return pipe, a gas-collecting hood and a plurality of gas outlet pipes. A bottom wall of an end of the condensation section adjacent to the evaporation section is defined as a second return wall. One end of the vapor pipe is in communication with the evaporation section, and the other end of the vapor pipe penetrates through the second return wall and is in communication with the condensation section. The vapor pipe protrudes from the second return wall. One end of the return pipe is in communication with the evaporation section, and the other end of the return pipe penetrates through the second return wall and is in communication with the condensation section. The return pipe does not protrude outward from the second return wall. The gas-collecting hood is disposed on the condensation section. The gas-collecting hood is provided with a gas-collecting groove. The gas-collecting groove is provided with an opening towards the second return wall. A bottom wall of an end of the gas-collecting hood away from the second return wall is defined as a first return wall. The first return wall is provided with a plurality of gas outlet through-holes disposed at intervals. Each of the plurality of gas outlet through-holes is in communication with the gas-collecting groove and corresponding one of plurality of gas outlet pipes. The plurality of gas outlet pipes protrude from the first return wall along a direction from the evaporation section to the condensation section. The gas-collecting hood is connected to a side wall of the condensation section, and a return gap is defined between the gas-collecting hood and the side wall of the condensation section, so that a liquid working medium in a side of the gas-collecting hood away from the second return wall is capable of returning between the gas-collecting hood and the second return wall via the return gap.

In an embodiment, the condensation section is provided with a plurality of vapor channels disposed at intervals. Each of the plurality of vapor channels is in communication with corresponding one of the plurality of gas outlet pipes. The heat exchange apparatus further includes an inner fin. The inner fin is disposed in each of the plurality of vapor channels.

In an embodiment, the inner fin includes a first condensing plate, a second condensing plate and a splitter plate. The splitter plate is connected to the first condensing plate and the second condensing plate. The first condensing plate and the second condensing plate are disposed at intervals along a width direction of the plurality of gas outlet pipes and are disposed at two sides of the plurality of gas outlet pipes, respectively.

In an embodiment, an end of the splitter plate towards the plurality of gas outlet pipes is provided with a splitter notch. The splitter notch is in a conical shape. A tip of the splitter notch faces the condensation section. A bottom of the splitter notch faces the evaporation section and is connected to the splitter plate. A direction from the evaporation section to the condensation section is defined as a preset height direction. An orthographic projection of the bottom of the splitter notch along the preset height direction is defined as a first projection. An orthographic projection of end surfaces of sides of the plurality of gas outlet pipes towards the condensation section along the preset height direction is defined as a second projection. Arrangement directions of both the first condensing plate and the second condensing plate are defined as a preset width direction. The second projection is totally covered by the first projection along the preset width direction.

In an embodiment, the conical splitter notch includes a first side wall and a second side wall disposed opposite to each other. The first side wall is intersected with the second side wall at the tip of the splitter notch. The first side wall extends from the tip of the splitter notch to the first condensing plate. The second side wall extends from the tip of the splitter notch to the second condensing plate.

In an embodiment, an end of the splitter plate away from the plurality of gas outlet pipes is provided with a splitter protruding piece. A tip of the splitter protruding piece faces the condensation section. A bottom of the splitter protruding piece faces the evaporation section and is connected to the splitter plate.

In an embodiment, the vapor pipe and the gas outlet pipe are separate from each other, so that the vapor pipe is in communication with the plurality of gas outlet pipes via the gas-collecting groove.

In an embodiment, an end of the return pipe in communication with the evaporation section extends to a bottom of the evaporation section away from the condensation section. An end of the vapor pipe in communication with the evaporation section is disposed at a top of the evaporation section adjacent to the condensation section.

In an embodiment, the gas-collecting hood further includes a peripheral flange, which encircles a side of the first return wall facing the second return wall and, together with the first return wall, and defines the gas-collecting groove.

In an embodiment, a peripheral side of the peripheral flange is provided with a plurality of protrusions distributed along a circumferential direction of the peripheral flange. Adjacent two of the plurality of protrusions are disposed at intervals, and the peripheral flange is connected to an inner wall of the condensation section via the plurality of protrusions.

In an embodiment, when the evaporation section and the condensation section are disposed along the preset height direction, the first return wall is obliquely disposed relative to a plane perpendicular to the preset height direction, and the return gap is located at a lowest side of the first return wall along the preset height direction.

The present disclosure further provides an inverter cooling system. The inverter cooling system includes the above heat exchanger apparatus.

The present disclosure further provides a converter cooling system. The converter cooling system includes the above heat exchanger apparatus.

Compared with related technology, when the heat exchange apparatus, the inverter cooling system, and the converter cooling system in the present disclosure is in use, the condensation section can be disposed above the evaporation section, so that the liquid working medium can automatically return by gravity. By such arrangement, a gaseous working medium in the evaporation section first enters the condensation section via the vapor pipe, and then continues to rise to the top of the condensation section via the gas outlet through-hole and the gas outlet pipe.

Moreover, since the plurality of gas outlet through-holes are disposed at intervals and in communication with the gas-collecting groove, after the gaseous working medium entering each of the plurality of gas outlet through-holes from the gas-collecting groove, a flow area of the gaseous working medium is reduced and a flow rate of the gaseous working medium is increased, so that the gaseous working medium can quickly rise to the top of the condensation section, facilitating fully cooling the gaseous working medium in the condensation section, thereby improving the heat exchange efficiency of the heat exchange apparatus.

When the gaseous working medium releases heat and condenses into the liquid working medium in the condensation section, since the gaseous working medium rapidly flows from the gas outlet pipe to the condensation section, under an impact of the gaseous working medium, the condensed and refluxing liquid working medium is difficult to enter the gas outlet pipe, i.e., most of the liquid working medium enters the first return wall when the liquid working medium is refluxing.

Then, the liquid working medium enters between the gas-collecting hood and the side wall of the condensation section from the first return wall, and a return gap is provided between the gas-collecting hood and the side wall of the condensation section, such that the condensed liquid working medium can return between the gas-collecting hood and the second return wall via the return gap.

Since the vapor pipe protrudes from the second return wall and the return pipe does not protrude outward from the second return wall, such that the liquid working medium entering the second return wall will enter the return pipe and return to the evaporation section. Moreover, the liquid working medium entering the second return wall is hard to enter the vapor pipe that is located at a higher height, so as to not affect a rise of the gas working medium in the vapor pipe.

Therefore, in the heat exchange apparatus of the present disclosure, the gas outlet pipe protrudes from the first return wall to realize a first gas-liquid separation, so as to prevent the rising gaseous working medium and the return liquid working medium from being mixed. By arranging the gas-collecting hood, the return gap configured for only the liquid working medium penetrating through and the gas-collecting groove configured for only the gaseous working medium penetrating through are formed, so that a second gas-liquid separation is realized. The vapor pipe protrudes from the second return wall to realize a third gas-liquid separation, so as to prevent the rising gaseous working medium and the return liquid working medium from being mixed. Therefore, the condensed and return liquid working medium is hard to be affected by and interfere with the rising gaseous working medium by three times of gas-liquid separation of the present disclosure.

Furthermore, both of the vapor pipe and the return pipe can be directly in communication with the evaporation section and the condensation section, i.e., the evaporation section, the condensation section, the vapor pipe and the return pipe can be disposed at the same plane, so that the volume of the heat exchange apparatus provided by the present disclosure is greatly reduced.

Details of one or more embodiments of this application are presented in the attached drawings and descriptions below. And other features, purposes and advantages of this application will become apparent from the description, drawings and claims.

### BRIEF DESCRIPTION OF THE DRAWINGS

For a better description and illustration of embodiments and/or examples of those disclosures disclosed herein, reference may be made to one or more attached drawings. Additional details or examples used to describe the drawings should not be considered as limiting the scope of any of the disclosed disclosures, currently described embodiments and/or examples, and currently understood best modes of these disclosures.

FIG. 1 is a schematic diagram of a heat exchanger of an embodiment in the present disclosure in a side view.

FIG. 2 is a schematic diagram of a heat exchanger of an embodiment in the present disclosure in a front view.

FIG. 3 is a first partial schematic diagram of a heat exchanger of an embodiment in the present disclosure.

FIG. 4 is a second partial schematic diagram of a heat exchanger of an embodiment in the present disclosure.

FIG. 5 is a partial schematic diagram of a heat exchanger of another embodiment in the present disclosure.

FIG. 6 is a schematic diagram of an assembly structure of an inner fin, a gas outlet pipe, a gas-collecting hood and a protrusion of an embodiment in the present disclosure.

FIG. 7 is a schematic diagram of an assembly structure of a gas outlet pipe, a gas-collecting hood, and a protrusion of an embodiment in the present disclosure.

FIG. 8 is a cross-sectional schematic view of the assembly structure in FIG. 7.

FIG. 9 is a schematic diagram of an inner fin of an embodiment in the present disclosure.

FIG. 10 is a schematic diagram of a fin unit of an embodiment in the present disclosure.

FIG. 11 is a schematic diagram of a fin unit of another embodiment in the present disclosure.

FIG. 12 is a schematic diagram of an assembly structure of an outer fin and a condensation section of an embodiment in the present disclosure.

FIG. 13 is a schematic diagram of a heat exchanger of another embodiment in the present disclosure in a side view.

FIG. 14 is a schematic diagram of a heat exchanger of another embodiment in the present disclosure in a side view.

Reference signals are as follows: 100 represents an evaporation section; 200 represents a condensation section; 210 represents a second return wall; 211 represents a first through hole; 212 represents a second through hole; 220 represents a vapor channel; 230 represents a collecting chamber; 240 represents an installation interval; 250 represents a balance cavity; 300 represents a vapor pipe; 400 represents a return pipe; 500 represents a gas-collecting hood; 510 represents a gas-collecting groove; 520 represents a first return wall; 521 represents a gas outlet through-hole; 530 represents a peripheral flange; 540 represents a protrusion; 550 represents a return gap; 560 represents an anti-liquid-accumulation gap; 600 represents a gas outlet pipe; 700 represents an inner fin; 710 represents a first condensing plate; 711 represents a first hollowed through-opening; 720 represents a second condensing plate; 721 represents a second hollowed through-opening; 730 represents a splitter plate; 731 represents a splitter notch; 732 represents a first side wall; 733 represents a second side wall; 740 represents a splitter protruding piece; 750 represents a fin unit; 800 represents an outer fin; and 900 represents a power element.

### DETAILED DESCRIPTION

The following will provide a clear and complete description of the technical solution in the embodiments of the present disclosure, in communication with the accompanying drawings. Obviously, the described embodiments are only a part of the embodiments of the present disclosure, not all of them. Based on the embodiments in the present disclosure, all other embodiments obtained by ordinary skill in this art without creative labor fall within the scope of protection of the present disclosure.

In apparatuses such as photovoltaic inverters and photovoltaic converters, power elements (including but not limited to insulated gate bipolar transistors (IGBT), chips, motors, and so on) inside the apparatuses are required to be cooled. At present, a heat pipe heat exchanger has a relatively great heat exchange effect. The heat pipe heat exchanger generally adopts an annular loop. Specifically, in the heat pipe heat exchanger, after a working medium in an evaporation section being heated and gasified, the working medium vapor is evaporated and conveyed to a condensation section via a plurality of pipelines, is condensed into a liquid working medium after being regularly cooled, and returns to the evaporation section via the liquid return pipe, so that whole circulation forms an annular loop.

A traditional heat pipe heat exchanger has the following problems: in order to make a layout of the heat pipe heat exchanger more compact, the evaporation section and the condensation section are disposed in the same plane, and the rising gaseous working medium and the falling liquid working medium share the same channel, so that vapor rising in the evaporation section and condensate returning from the condensation section may be effected/interfered with each other, thereby affecting heat exchange efficiency of the heat pipe heat exchanger.

In order to solve the above problem that the rising vapor interferes with the return condensation liquid, the present disclosure provides a heat exchanger apparatus, an inverter cooling system and a converter cooling system.

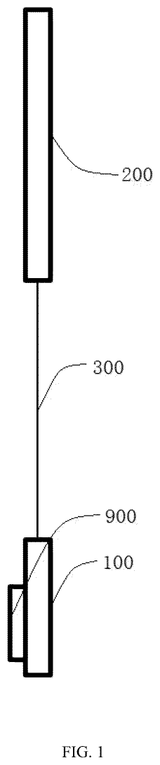

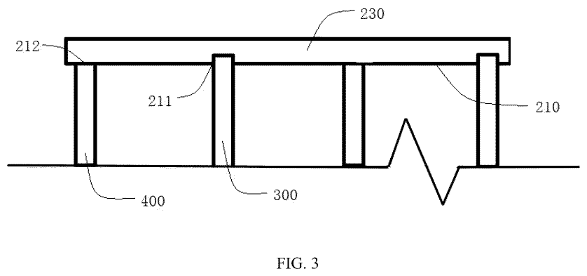

Referring to FIGS. 1 to 14, the heat exchange apparatus includes an evaporation section 100, a condensation section 200, a vapor pipe 300, a return pipe 400, a gas collection hood 500 and a gas outlet pipe 600. A bottom wall of an end of the condensation section 200 towards the evaporation section 100 is defined as a second return wall 210. The second return wall 210 is provided with a first through hole 211 and a second through hole 212. One end of the vapor pipe 300 is in communication with the evaporation section 100, and the other end of the vapor pipe 300 is in communication with the condensation section 200 via the first through hole 211. An end of the vapor pipe 300 in communication with the condensation section 200 protrudes from the second return wall 210. One end of the return pipe 400 is in communication with the evaporation section 100, and the other end of the return pipe 400 penetrates through the second through hole 212 and is in communication with the condensation section 200. An end of the return pipe 400 in communication with the condensation section 200 does not protrude outward from the second return wall 210.

It should be noted that “the vapor pipe 300 protrudes from the second return wall 210” means that the vapor pipe 300 continues to extend a distance into the condensation section 200 after penetrating through the first through hole 211, such that the vapor pipe 300 protrudes outward from the second return wall 210.

Specifically, a height of the vapor tube 300 protruding from the second return wall 210 is in a range of 1 mm and 5 mm (including 1 mm and 5 mm).

Correspondingly, “the return pipe 400 does not protrude outward from the second return wall 210” means that after the return pipe 400 being in communication with the second through hole 212, the return pipe 400 does not extend into the condensation section 200, such that the return pipe 400 is lower than or flush with the second return wall 210.

Furthermore, it should be noted that two ends of the vapor pipe 300 are hermetically welded (or clamped) to the evaporation section 100 and the condensation section 200, respectively. Two ends of the return pipe 400 are hermetically welded (or clamped) to the evaporation section 100 and the condensation section 200, respectively.

In an embodiment, the number of the first through holes 211 and the number of the second through holes 212 are both multiple. A plurality of first through holes 211 and a plurality of second through holes 212 can be alternately disposed.

By such arrangement, the vapor pipe 300 can uniformly cover the entire condensation section 200, and the return pipe 400 can uniformly cover an entire evaporation section 100, facilitating uniform heat exchange of each part of the heat exchange apparatus.

The number of the first through hole 211 and the number of the second through hole are not limited herein. In another embodiment, the number of the first through hole 211 and the number of the second through hole 212 can be both one.

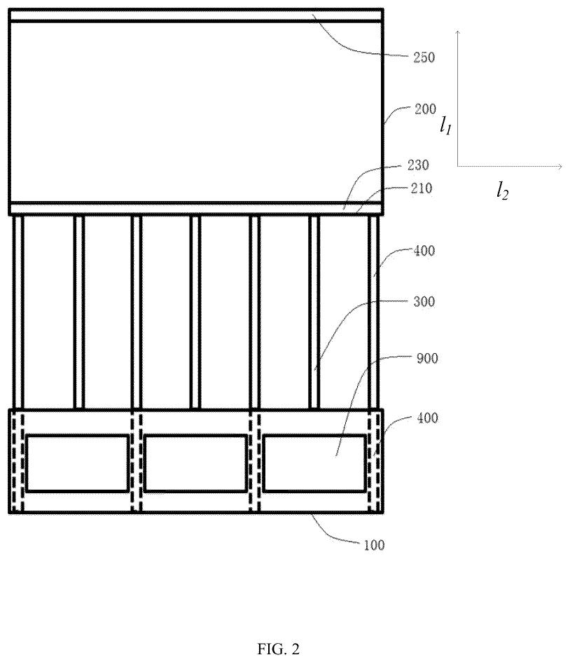

In an embodiment, referring to FIG. 2, an end of the return pipe 400 in communication with the evaporation section 100 extends to a bottom of the vapor pipe 100 away from the condensation section 200. An end of the vapor pipe 300 in communication with the evaporation section 100 is disposed on a top of the evaporation section 100 adjacent to the condensation section 200.

By such arrangement, mutual interference between the gaseous working medium and the liquid working medium in the evaporation section 100 can be avoided.

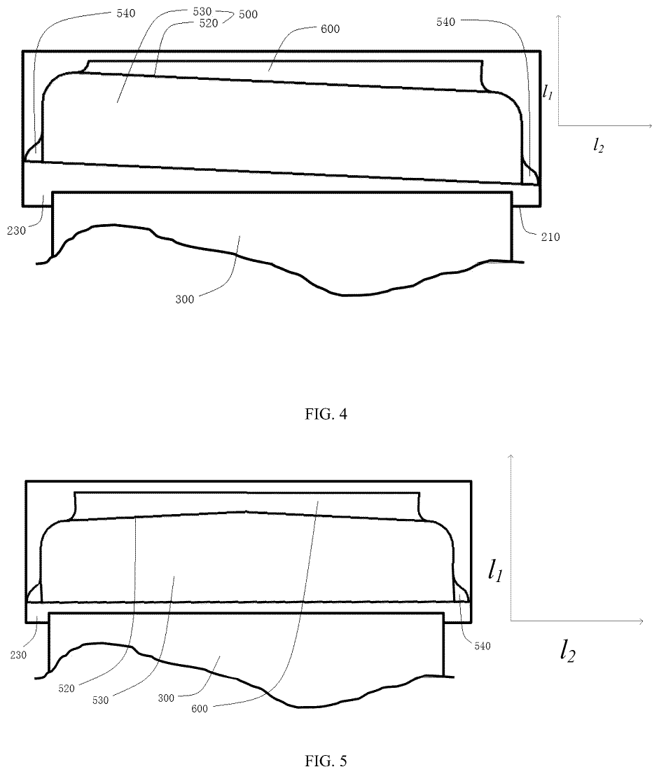

Referring to FIGS. 4 to 8, the gas-collecting hood 500 is disposed at an end of the condensation section 200 adjacent to the evaporation section 100. The gas-collecting hood 500 is provided with a gas-collecting groove 510. The gas-collecting groove 510 includes an opening towards the second return wall 210. A bottom wall of an end of the gas-collecting hood 500 away from the second return wall 210 is defined as a first return wall 520. The first return wall 520 is provided with a plurality of gas outlet through-holes 521 disposed at intervals. Each of the gas outlet through-holes 521 is in communication with the gas-collecting groove 510 and a corresponding one of the plurality of gas outlet pipe 600. The plurality of gas outlet pipes 600 protrude from the first return wall 520 along a direction from the evaporation section 100 to the condensation section 200.

Specifically, in an embodiment, the plurality of gas outlet pipes 600 are integrated with the gas-collecting hood 500.

Specifically, the plurality of gas outlet pipes 600 are formed by stamping the gas-collecting hood 500. Alternatively, the gas-collecting hood 500 and the gas outlet pipe 600 are integrally cast and formed; or, the gas-collecting hood 500 and the gas outlet pipe 600 are formed by 3D printing.

In another embodiment, the plurality of gas outlet pipes 600 and the gas-collecting hood 500 may be formed by welding.

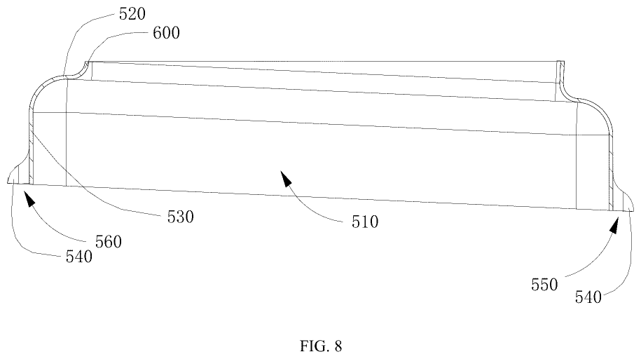

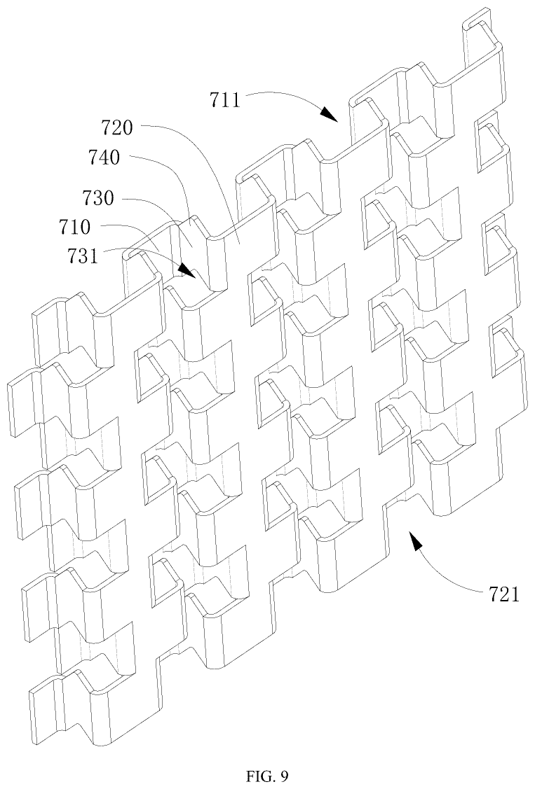

Furthermore, referring to FIG. 8, the gas-collecting hood 500 is connected to a side wall of the condensation section 200. A return gap 550 is defined between the gas-collecting hood 500 and the condensation section 200, such that the liquid working medium of an end of the gas-collecting hood 500 away from the second return wall 210 can return between the gas-collecting hood 500 and the second return wall 210 via the return gap 550.

When the heat exchange apparatus is in use, the condensation section 200 may be disposed above the evaporation section 100, so that the liquid working medium can automatically return by gravity. By such arrangement, the gaseous working medium in the evaporation section 100 firstly enters into the condensation section 200 via the vapor pipe 300, and then continues to rise to a top of the condensation section 200 through the gas outlet through-hole 521 and the plurality of gas outlet pipes 600.

Moreover, since the plurality of gas outlet through-holes 521 are disposed at intervals and in communication with the gas-collecting groove 510, after the gaseous working medium entering into each of the plurality of gas outlet through-holes 521 from the gas-collecting groove 510, a flow area of the gaseous working medium is reduced and a flow rate of the gaseous working medium is increased, so that the gaseous working medium can quickly rise to the top of the condensation section 200, facilitating fully cooling the gaseous working medium in the condensation section 200. Therefore, the heat exchange efficiency of the heat exchange apparatus can be improved.

When the gaseous working medium releases heat and condenses into the liquid working medium in the condensation section 200, since the gaseous working medium rapidly flows from the gas outlet pipe 600 to the condensation section 200, under an impact of the gaseous working medium, the condensed and return liquid working medium is difficult to enter into the gas outlet pipe 600, i.e., most of the liquid working medium enters to the first return wall 520 during return of the liquid working medium.

Then, the liquid working medium from the first return wall 520 enters between the gas-collecting hood 500 and the side wall of the condensation section 200, and the return gap 550 is defined between the gas-collecting hood 500 and the side wall of the condensation section 200, such that the condensed liquid working medium can return between the gas-collecting hood 500 and the second return wall 210 via the return gap 550.

Since the vapor pipe 300 protrudes from the second return wall 210 and the return pipe 400 does not protrude outward from the second return wall 210, such that the liquid working medium entering to the second return wall 210 will enter into the return pipe 400 and return to the evaporation section 100. Moreover, the liquid working medium entering the second return wall 210 is hard to enter the vapor pipe 300 that is located at a higher height, so as to not affect a rise of the gas working medium in the vapor pipe 300.

It can be seen from the above description, in the heat exchange apparatus of the present disclosure, the plurality of gas outlet pipes 600 protrude from the first return wall 520 to realize a first gas-liquid separation, so as to prevent the rising gaseous working medium and the return liquid working medium from being mixed. By arranging the gas-collecting hood 500, the return gap 550 configured for only the liquid working medium flowing/passing through and the gas-collecting groove 510 configured for only the gaseous working medium flowing/passing through are formed, so that a second gas-liquid separation is realized. The vapor pipe 300 protrudes from the second return wall 210 to realize a third gas-liquid separation, so as to prevent the rising gaseous working medium and the return liquid working medium from being mixed. Therefore, the condensed and return liquid working medium is hard to be interfered with the rising gaseous working medium by three times of gas-liquid separation of the present disclosure.

Furthermore, the vapor pipe 300 and the return pipe 400 can be directly in communication with the evaporation section 100 and the condensation section 200, respectively, i.e., the evaporation section 100, the condensation section 200, the vapor pipe 300 and the return pipe 400 can be disposed at the same plane, so that a volume of the heat exchange apparatus provided by the present disclosure is greatly reduced.

In an embodiment, referring to FIGS. 4 and 5, the vapor pipe 300 is separated from the gas outlet pipe 600, so that the vapor pipe 300 can be in communication with the gas outlet pipe 600 via the gas-collecting groove 510.

By such arrangement, the gaseous working medium first enters into the gas-collection groove 510 when the gaseous working medium leaves from the vapor pipe 300, and then the gaseous working medium is mixed in the gas-collection groove 510. The gas-collection groove 510 located between the vapor pipe 300 and the gas outlet pipe 600 can play a role of balancing air pressure, so that the air pressure of the gaseous working medium entering into each of the plurality of gas outlet pipes 600 is equal, facilitating uniform releasing heat at each part of the condensation section 200.

However, in another embodiment, the vapor pipe 300 may be directly in communication with the gas outlet pipe 600. Specifically, the vapor pipe 300 sequentially penetrates through the gas-collecting groove 510 and the gas outlet through-hole 521, and the gas outlet pipe 600 is formed by a part of the vapor pipe 300 protruding from the first return wall 520.

By such arrangement, the number of components required by the heat exchange apparatus is reduced, and assembly difficulty of the heat exchange apparatus is reduced.

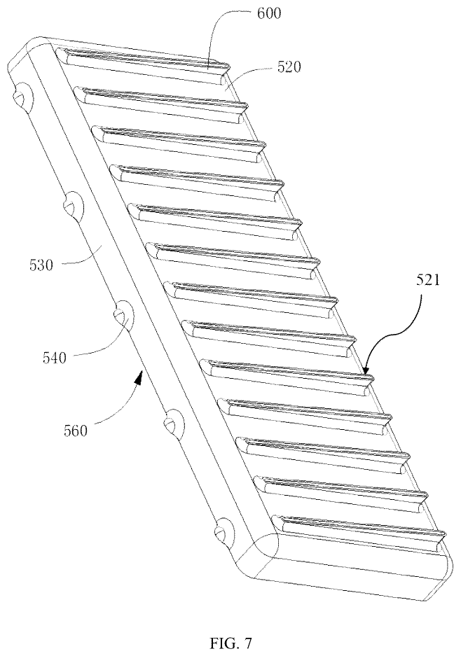

In an embodiment, referring to FIG. 7 and FIG. 8, the gas-collecting hood 500 includes a first return wall 520 and a peripheral flange 530. The peripheral flange 530 encircles a side of the first return wall 520 facing the second return wall 210 and, together with the first return wall 520, defines the gas-collecting groove 510.

Specifically, the first return wall 520 is integrated with the peripheral flange 530.

More specifically, the first return wall 520 and the peripheral edge 530 are formed by stamping or 3D printing.

Alternatively, the first return wall 520 and the peripheral edge 530 are formed by welding to each other.

In an embodiment, the gas-collecting hood 500 is connected to an inner wall of a housing of the heat exchange apparatus via an end of the peripheral flange 530 adjacent to the evaporation section 100. The return gap 550 is disposed between the peripheral flange 530 and the housing.

By such arrangement, the return gap 550 may be disposed at a lowest portion of the gas-collecting hood 500, such that the liquid working medium on a surface of the gas-collecting hood 500 may flow into the evaporation section 100 via the return gap 550, thereby avoiding the liquid working medium from accumulating on a surface of the gas-collection hood 500.

Furthermore, in an embodiment, referring to FIG. 4 to FIG. 8, a peripheral side of the peripheral flange 530 is provided with a plurality of protrusions 540 distributed along a circumferential direction of the peripheral flange 530, adjacent two of the plurality of protrusions 540 are disposed at intervals. The peripheral flange 530 is connected to (including but not limited to welding, clamping or bonding) an inner wall of the condensation section 200 via the plurality of protrusions 540.

By such arrangement, the peripheral flange 530 is separated from the inner wall of the condensation section 200, and the return gap 550 is defined by the adjacent two of the plurality of protrusions 540, the side wall of the peripheral flange 530, and the inner wall of the condensation section 200, so as to greatly reducing processing difficulty of the return gap 550.

Furthermore, in an embodiment, the peripheral flange 530 is integrated with the gas-collecting hood 540.

The plurality of protrusions 540 are formed by stamping the peripheral flange 530. Alternatively, the peripheral flange 530 and the plurality of protrusions 540 are integrally cast and formed. Alternatively, the peripheral flange 530 and the plurality of protrusion 540 are formed by 3D printing.

In another embodiment, the peripheral flange 530 and the plurality of protrusions 540 may be formed by welding.

In another embodiment, the gas-collecting hood 500 can be connected to an inner wall of the condensation section 200 via an end of the peripheral flange 530 adjacent to the evaporation section 200, and the return gap 550 is disposed between the end of the peripheral flange 530 adjacent to the condensation section 200 and the inner wall of the condensation section 200.

In an embodiment, referring to FIG. 4, when the evaporation section 100 and the condensation section 200 are arranged along a preset height direction l1, the first return wall 520 is obliquely disposed relative to a direction perpendicular to the preset height direction l1. The return gap 550 is located at a lowest side of the first return wall along the preset height direction l1.

When the condensation section 200 is disposed above the evaporation section 100, it is beneficial for the liquid working medium returning to the first return wall 520 to flow towards the return gap 550 under the action of gravity, i.e., it is beneficial for all the liquid working medium to return quickly.

Furthermore, in an embodiment, a power element 900 is disposed on a side of the evaporation section 100 adjacent to the return gap 550, so that the return liquid working medium can quickly take away heat of the power element 900.

Furthermore, the power element 900 may be immersed in or partially immersed in the liquid working medium of the evaporation section 100. The power element 900 may abut against to an outer wall of the evaporation section 100.

Furthermore, in an embodiment, referring to in FIGS. 7 and 8, an anti-liquid-accumulation gap 560 is defined between the peripheral flange 530 located on a highest side of the first return wall 520 along the preset height direction and the inner wall of the condensation section 200. The anti-effusion gap 560 is in communication with the evaporation section 100 and the condensation section 200.

By providing the anti-liquid-accumulation gap 560, liquid accumulation between the peripheral flange 530 located at the highest side of the first return wall 520 and the housing may be prevented.

Furthermore, in an embodiment, when the evaporation section 100 and the condensation section 200 are disposed along the preset height direction l₁. An end surface of each of the plurality of gas outlet pipes 600 towards the condensation section 200 is disposed along a direction perpendicular to the preset height direction l₁.

By such arrangement, it is beneficial for the gaseous working medium, which is located at all positions of the plurality of gas outlet pipes 600, to simultaneously leave the plurality of gas outlet pipes 600 to move upward.

Furthermore, in other embodiments, when the evaporation section 100 and the condensation section 200 are arranged along the preset height direction l₁, an end surface of a side of the gas outlet pipe 600 towards the condensation section 200 is parallel to the first return wall 520.

By such arrangement, it is beneficial for a flow distance of the gaseous working medium, which is located at all parts of the plurality of gas outlet pipes 600, to be consistent in the gas outlet pipe 600, i.e., it is beneficial for an initial speed of the gaseous working medium, which is located at all positions in the gas outlet pipe 600, to be consistent in the gas outlet pipe 600.

In another embodiment, when the evaporation section 100 and the condensation section 200 are arranged along the preset height direction l₁, the first return wall 520 may be disposed along the direction perpendicular to the preset height direction l₁.

In another embodiment, referring to FIG. 5, when the evaporation section 100 and the condensation section 200 are disposed along the preset height direction l₁, the first return wall 520 is in a state of being higher in the middle and lower in the two ends which is relative to the direction perpendicular to the preset height direction, and the first return wall 520 is provided with return gaps 550 at two sides of the first return wall 520 which are located at lowest side of the first return wall 520 along the preset high direction l_{1.}

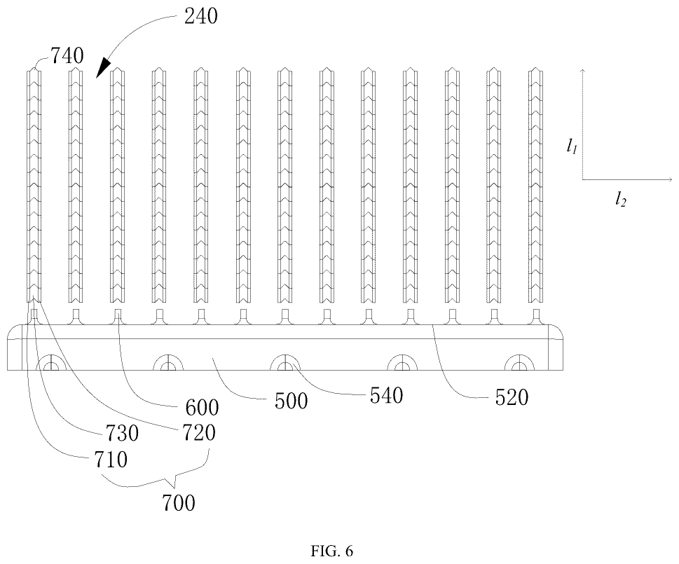

In an embodiment, referring to FIG. 6, the condensation section 200 is provided with a plurality of vapor channels 220 disposed at interval and in communication with corresponding one of the plurality of gas outlet pipes 600, respectively. The heat exchange apparatus further includes an inner fin 700. The inner fin 700 is disposed in each of the plurality of vapor channels 220 and connected to (including but not limited to welding, clamping and so on) an inner wall of each of the plurality of vapor channels 220.

By such arrangement, it facilitates enlarging an attachment surface area of the gaseous working medium, so that the gaseous working medium can be fully condensed in the condensation section 200 to release heat, facilitating improving the heat exchange efficiency of the heat exchange apparatus.

It can be understood that a collecting chamber 230 in communication with each of the plurality of vapor channels 220 is formed by the inner fin 700 and the second return wall 210 separating from each other. The gas-collecting hood 500 is disposed in the collecting chamber 230.

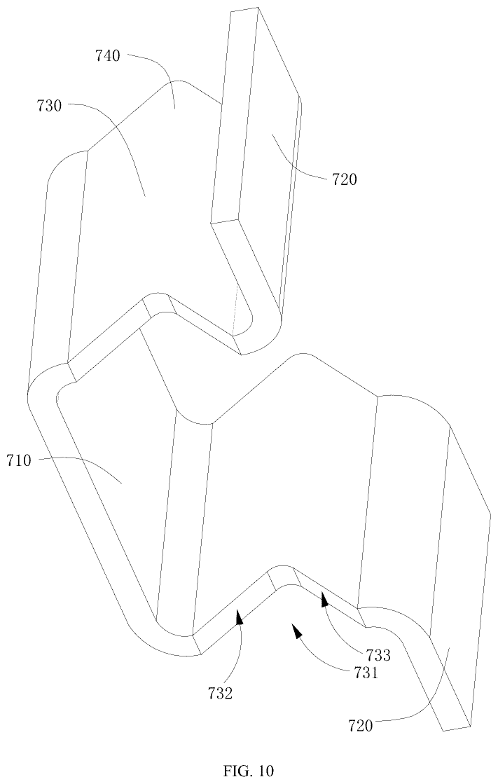

Furthermore, in an embodiment, referring to FIGS. 9 to 11, the inner fin 700 includes a first condensing plate 710, a second condensing plate 720 and a splitter plate 730. The splitter plate 730 is connected to and in communication with the first condensing plate 710 and the second condensing plate 720. The first condensing plate 710 and the second condensing plate 720 are disposed at interval along a width direction of the plurality of gas outlet pipes 600 and disposed at two sides of the plurality of gas outlet pipes 600, respectively.

It should be noted that the first condensing plate 710 and the second condensing plate 720 may be arranged in parallel or approximately in parallel.

By such arrangement, the gaseous working medium can be cooled and condensed on the first condensing plate 710 with a large area and the second condensing plate 720 with a large area. By the splitter plate 730, on one hand, a surface area of the inner fin 700 can be increased, and on the other hand, strength of the inner fin 700 can be increased.

Furthermore, in an embodiment, referring to FIGS. 9 to 11, an end of the splitter plate 730 towards the gas outlet pipe 600 is provided with a conical splitter notch 731. A tip of the splitter notch 731 faces the condensation section 200. A bottom of the splitter notch 731 faces the evaporation section 100.

It should be noted that the splitter notch 731 is an imaginary body, so that a shape of the splitter notch 731 is an imaginary body shape defined by a boundary of the splitter plate 730. The conical splitter notch 731 includes various types.

Specifically, in an embodiment, referring to FIGS. 9 to 10, the conical splitter notch 731 may be regarded as a triangular. A tip of the splitter notch 731 is a vertex angle of the triangle, and a bottom of the splitter notch 731 is a bottom edge of the triangle.

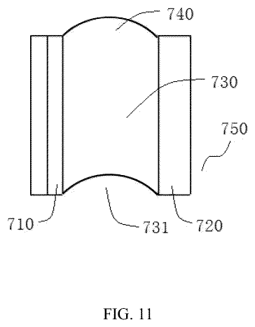

In another embodiment, referring to FIG. 11, the conical splitter notch 731 may be in an arcuate shape, i.e., an inner wall of the splitter notch 731 is in an arc shape. A tip of the splitter notch 731 is an end of the splitter notch 731 away from a circle center of the inner wall of the splitter notch 731. A bottom end of the splitter notch 731 is an end of the splitter notch 731 adjacent to the circle center of the inner wall of the splitter notch 731.

A direction from the evaporation section to the condensation section is defined as a preset height direction l₁. An orthographic projection of a bottom end of the splitter notch along the preset height direction is defined as a first projection. An orthographic projection of end faces of the gas outlet pipes 600 towards the condensation section 200 along the preset height direction is defined as a second projection.

It should be noted that “the orthographic projection of the bottom of the splitter notch 731 along the preset height direction” refers to an orthographic projection of the bottom of the splitter notch 731 on a plane perpendicular to the preset height direction l₁. “The orthographic projection of the end surface of the side of the gas outlet pipe 600 towards the condensation section 200 along the preset height direction” refers to the orthographic projection of the end surface of the side of the gas outlet pipe 600 towards the condensation section 200 on a plane perpendicular to the preset height direction l₁.

A reason of adopting the orthographic projection of the bottom of flow distribution 731 and the orthographic projection of the end surface of the gas outlet pipe 600 along the preset height direction l₁ is a vertical direction is that the condensing section 200 is disposed above the evaporating section 100 when the heat exchange apparatus is in use. Therefore, the preset height direction l₁ is regarded as a vertical direction, and both of the first projection and the second projection are projections located on a plane perpendicular to the preset high direction l₁.

Arrangement directions of both the first condensing plate 710 and the second condensing plate 720 are defined as a preset width direction l₂. The second projection is totally covered by the first projection.

It can be understood that “in the preset width direction l₂, the second projection is totally covered by the first projection” not only means that a width of the first projection is greater than a width of the second projection. When the liquid working medium on two sides of the bottom of the splitter notch 731 vertically falls, the liquid working medium can only drop on the two sides of each of the plurality of gas outlet pipes 600, and cannot drop on the plurality of gas outlet pipes 600. Since the splitter notch 731 is in a conical shape, the liquid working medium flows from the tip of the splitter notch 731 to the two sides of the bottom of the splitter notch 731 along the inner wall of the splitter notch 731, and finally drops on the two sides of the gas outlet pipe 600.

Obviously, by arranging the inner fin 700 and arranging the splitter notch 731 on the splitter plate 730, condensed water condensed on the splitter plate 730 can completely avoid the plurality of gas outlet pipes 600 in a return process. Since the first condensing plate 710 and the second condensing plate 720 are arranged on the two sides of the plurality of gas outlet pipes 600 along the preset width direction l₂, respectively, the liquid working medium dropped from the first condensing plate 710 and the second condensing plate 720 can totally avoid the plurality of gas outlet pipes 600. Therefore, it can be seen that the liquid working medium returning on the entire inner fin 700 can fully avoid the plurality of gas outlet pipes 600, thereby not only effectively avoiding interference between the gaseous working medium in the plurality of gas outlet pipes 600 and the liquid working medium returning from the condensation section 200, but also greatly increasing condensation efficiency of the condensation section 200 by arranging the inner fin 700.

In an embodiment, referring to FIG. 10, the conical splitter notch 731 is provided with two side walls opposite to each other. The two side walls opposite to each other are defined as a first side wall 732 and a second side wall 733, respectively. The first side wall 732 and the second side wall 733 are intersected with each other at the tip of the splitter notch 731. The first side wall 732 extends from the tip of the splitter notch 731 to the first condensing plate 710. The second side wall 733 extends from the tip of the splitter notch 731 to the second condensing plate 720.

By such arrangement, the liquid working medium condensed on the splitter plate 730 can return to the first condensing plate 710 and the second condensing plate 720, respectively, via the first side wall 732 and the second side wall 733 of the splitter notch 731, i.e., it facilitates concentrated return of the liquid working medium on the inner fin 700, and a distance between the return liquid working medium and the return gaseous working medium is further increased.

Specifically, in an embodiment, both the first sidewall 732 and the second sidewall 733 are planar. An included angle between the first sidewall 732 and the second sidewall 733 is defined as A. The included angle A satisfies the following relationship: the included angle A is greater or equal to 45 degrees and less than or equal to 170 degrees.

In another embodiment, when the splitter notch 731 is in an arcuate shape, both the first side wall 732 and the second side wall 733 are in a part of a circle shape, respectively. An arc is formed by the first side wall 732 and the second side wall 733.

In an embodiment, the number of the splitter plates 730 is multiple. A plurality of splitter plates 730 are alternately distributed between the first condensing plate 710 and the second condensing plate 720.

In an embodiment, the first condensing plate 710, the second condensing plate 720 and the splitter plate 730 are integrally formed.

Specifically, the first condensing plate 710, the second condensing plate 720 and the splitter plate 730 are integrally formed by stamping. Alternatively, the first condensing plate 710, the second condensing plate 720 and the splitter plate 730 are formed by 3D printing.

In an embodiment, referring to FIG. 9, the first condensing plate 710 is provided with a plurality of first hollowed through-openings 711. The second condensing plate 720 is provided with a plurality of second hollowed through-openings 721. By such arrangement, on one hand, the plurality of first hollowed through-openings and the plurality of second hollowed through-openings 721 are formed by stamping, and on the other hand, the plurality of first hollowed through-openings 711 and the plurality of second hollowed through-openings 721 facilitate reducing a weight of the inner fin 700 and lightweighting the heat exchanger apparatus.

In an embodiment, referring to FIGS. 9 to 11, one end of the splitter plate 730 towards the gas outlet pipe 600 is provided with a splitter protruding piece 740. The splitter protruding piece 740 can be in a conical shape. A tip of the splitter protruding piece 740 faces the condensation section 200. A bottom of the splitter notch 740 faces the evaporation section 100 and is connected to the splitter plate 730.

By such arrangement, the splitter protruding piece 740 can play a role of guiding a flow, so that the liquid working medium returning to the splitter protruding piece 740 can quickly flow to the first condensing plate 710 and the second condensing plate 720 disposed on two sides of the splitter plate 730, respectively. The liquid working medium located on a wall surface of the splitter protruding piece 740 can be prevented from dropping from the middle of the inner fin 700 to the plurality of gas outlet pipes 600.

Specifically, the splitter protruding piece 740 may be in a triangular shape or in an arcuate shape. Moreover, the splitter protruding piece 740 and the splitter plate 730 are integrally formed or welded.

In an embodiment, referring to FIGS. 9 to 11, the inner fin 700 includes a plurality of fin units 750. Adjacent two of the plurality of fin units 750 are disposed in a staggered manner.

Specifically, the plurality of fin units 750 may be integrally formed or welded.

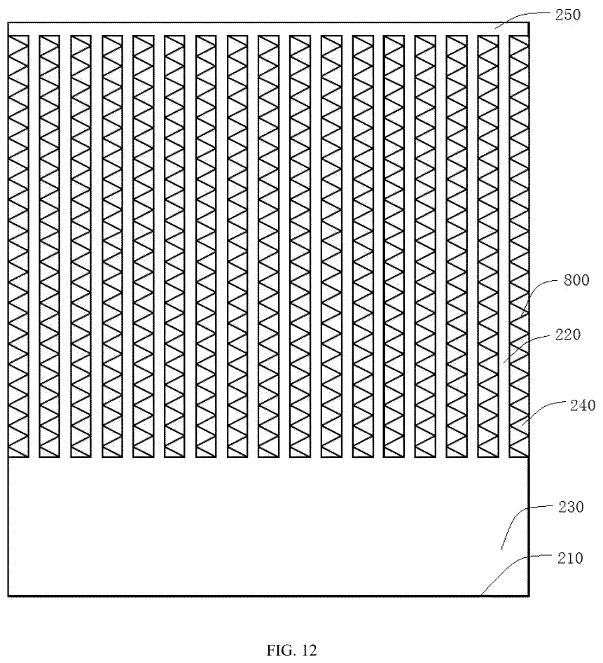

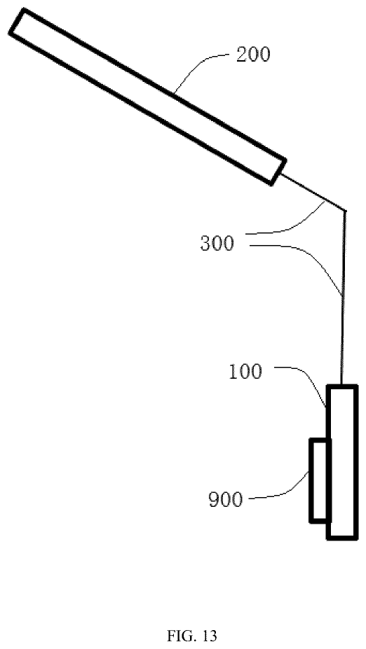

In an embodiment, referring to FIG. 12, a mounting interval 240 in communication with an external space is defined as adjacent two of the plurality of vapor channels 220 arranged at intervals. The mounting interval 240 is not in communication with the adjacent two of the plurality of vapor channels 220. The heat exchange apparatus further includes an outer fin 800. The outer fins 800 are mounted in the mounting interval 240, so that heat of the gaseous working medium in the vapor channels 220 can be transferred to the outer fins 800 and transferred to the external space through the outer fins 800.

Furthermore, in an embodiment, referring to FIG. 2 and FIG. 12, the condensation section 200 is further provided with a balance cavity 250. The balance cavity 250 is disposed on a side of the vapor channel 220 away from the gas collection hood 500, and the plurality of vapor channels 220 are in communication with the balance cavity 250 for balancing the air pressure in each of the plurality of vapor channels 220.

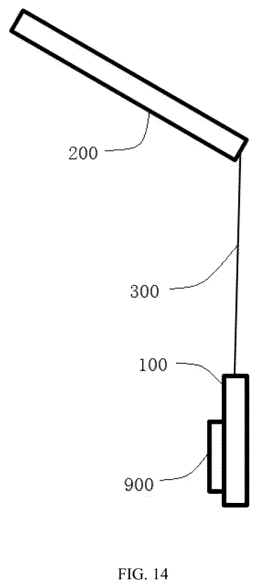

In order to adapt to different installation environments, in other embodiments, referring to FIG. 13 and FIG. 14, the evaporation section 100 and the condensation section 200 may not be disposed on the same plane. Specifically, the evaporation section 100 and the condensation section 200 are disposed obliquely relative to each other. The vapor pipe 300 and the return pipe 400 may be disposed vertically or may be disposed in a bent manner.

The present disclosure further provides an inverter cooling system. The inverter cooling system includes the heat exchange apparatus of any one of the above embodiments.

The present disclosure further provides a converter cooling system. The converter cooling system includes the heat exchange apparatus of any one of the above embodiments.

The various technical features of the above embodiments can be combined in any way. In order to make the description concise, not all possible combinations of the various technical features in the above embodiments have been described. However, as long as there is no contradiction in the combination of these technical features, they should be considered within the scope of the specification. In order to make the description concise, all possible combinations of the technical features in the foregoing embodiments are not described, however, as long as there is no contradiction between the combinations of the technical features, it should be considered as the scope of the description.

The above examples only express several implementations of the present disclosure, and the description thereof is specific and detailed, but cannot be construed as limiting the scope of the present disclosure. It should be noted that, for a person of ordinary skill in the art, several variations and improvements may be made without departing from the concept of the present disclosure, which all belong to the protection scope of the present disclosure. Therefore, the scope of protection of the present disclosure should be based on the attached claims.

In the description of the present disclosure, it should be understood that the terms “center”, “longitudinal”, “transversely”, “length”, “width”, “thickness”, “up”, “down”, “left”, “right”, “vertical”, “horizontal”, “top”, “bottom”, “inside”, “outside”, “clockwise”, “counterclockwise”, “axial”, “radial”, “circumferential” and so on denoting an orientation or a position relationship are based on the orientation or the position relationship shown in the attached drawings, it is just for convenience and simple to describe the present disclosure, but not indicating or implying an apparatus and a device having a specific orientation, constructing and operating in a specific orientation, therefore cannot be understood as limiting the present disclosure.

In addition, the terms “first” and “second” are only used to describe the purpose and can not be understood as indicating or implying relative importance or implying the quantity of indicated technical features. Therefore, the features limited to “first” and “second” can explicitly or implicitly include at least one of these features. In the description of the present disclosure, “multiple” means at least two, such as two, three, etc., unless there is an otherwise specific limitation.

In the present disclosure, unless otherwise specified and limited, the terms “installation”, “contact”, “connection”, “fixation” and so on should be broadly understood. For example, it may be a fixed connection, a detachable connection, or integrated; it may be a mechanical connection or an electrical connection; and it may be directly connected or indirectly connected through an intermediate medium, and may be a connection within two components or an interaction relationship between two components, unless otherwise specified. For ordinary skilled in the field, the specific meanings of the above terms in the present disclosure may be understood as required. For ordinary skill in the art, specific meanings of the above terms in the present disclosure may be understood by specific situations.

In the present disclosure, unless there is the otherwise specifications and limitations, the first feature is “above” or “below” the second feature which may be a direct contact between the first and second features, or the first features and the second features may be in indirect contact through an intermediate medium. Moreover, the first feature is “on”, “above”, and “over” the second feature can be that the first feature is directly or diagonally above the second feature, or only indicates that the first feature is horizontally higher than the second feature. The first feature is “beneath”, “below”, and “under” the second feature can be that the first feature is directly or diagonally below the second feature, or only indicate that the horizontal height of the first feature is less than that of the second feature.

It should be noted that, when a member is considered “fixed to” or “set on” another member, it can be directly disposed another member or there may be a centered member present simultaneously. When a member is considered “connected to” another member, it can be directly connected to another member or there may be a centered member present simultaneously. The terms “vertical”, “horizontal”, “left”, “right” and similar expressions used in the specification of the present disclosure are for illustrative purposes only and do not represent the only implementation method.

Unless otherwise defined, all technical and scientific terms used in this article have the same meanings as those commonly understood by those skilled in the art of the present disclosure. The terms used in the specification of the present disclosure are only for the purpose of describing specific embodiments and are not intended to limit the present disclosure. The term “and/or” used in this article includes any and all combinations of one or more related listed items.

What is claimed is:

1. A heat exchange apparatus, comprising an evaporation section, a condensation section, a vapor pipe, a return pipe, a gas-collecting hood and a plurality of gas outlet pipes, wherein a bottom wall of an end of the condensation section adjacent to the evaporation section is defined as a second return wall; one end of the vapor pipe is in communication with the evaporation section, the other end of the vapor pipe penetrates through the second return wall and is in communication with the condensation section, and the vapor pipe protrudes from the second return wall; one end of the return pipe is in communication with the evaporation section, the other end of the return pipe penetrates through the second return wall and is in communication with the condensation section, and the return pipe does not protrude outward from the second return wall;
the gas-collecting hood is disposed on the condensation section, the gas-collecting hood is provided with a gas-collecting groove, the gas-collecting groove is provided with an opening towards the second return wall, a bottom wall of an end of the gas-collecting hood away from the second return wall is defined as a first return wall, the first return wall is provided with a plurality of gas outlet through-holes disposed at intervals, each of the plurality of gas outlet through-holes is in communication with the gas-collecting groove and corresponding one of plurality of gas outlet pipes, and the plurality of gas outlet pipes protrude from the first return wall along a direction from the evaporation section to the condensation section; and
the gas-collecting hood is connected to a side wall of the condensation section, and a return gap is defined between the gas-collecting hood and the side wall of the condensation section, so that a liquid working medium in a side of the gas-collecting hood away from the second return wall is capable of returning between the gas-collecting hood and the second return wall via the return gap.

2. The heat exchange apparatus of claim 1, wherein the condensation section is provided with a plurality of vapor channels disposed at intervals, each of the plurality of vapor channels is in communication with corresponding one of the plurality of gas outlet pipes, the heat exchange apparatus further comprises an inner fin, and the inner fin is disposed in each of the plurality of vapor channels.

3. The heat exchange apparatus of claim 2, wherein the inner fin comprises a first condensing plate, a second condensing plate and a splitter plate, the splitter plate is connected to the first condensing plate and the second condensing plate, and the first condensing plate and the second condensing plate are disposed at intervals along a width direction of the plurality of gas outlet pipes and are disposed at two sides of the plurality of gas outlet pipes, respectively.

4. The heat exchange apparatus of claim 3, wherein the first condensing plate is provided with a plurality of first hollowed through-openings, the second condensing plate is provided with a plurality of second hollowed through-openings.

5. The heat exchange apparatus of claim 3, wherein an end of the splitter plate towards the plurality of gas outlet pipes is provided with a splitter notch, the splitter notch is in a conical shape, a tip of the splitter notch faces the condensation section, and a bottom of the splitter notch faces the evaporation section;
a direction from the evaporation section to the condensation section is defined as a preset height direction, an orthographic projection of the bottom of the splitter notch along the preset height direction is defined as a first projection, and an orthographic projection of end surfaces of sides of the plurality of gas outlet pipes towards the condensation section along the preset height direction is defined as a second projection; and
arrangement directions of both the first condensing plate and the second condensing plate are defined as a preset width direction, wherein the second projection is totally covered by the first projection along the preset width direction.

6. The heat exchange apparatus of claim 5, wherein the conical splitter notch comprises a first side wall and a second side wall disposed opposite to each other, the first side wall is intersected with the second side wall at the tip of the splitter notch, the first side wall extends from the tip of the splitter notch to the first condensing plate, and the second side wall extends from the tip of the splitter notch to the second condensing plate.

7. The heat exchange apparatus of claim 3, wherein an end of the splitter plate away from the plurality of gas outlet pipes is provided with a splitter protruding piece, a tip of the splitter protruding piece faces the condensation section, and the bottom of the splitter protruding piece faces the evaporation section and is connected to the splitter plate.

8. The heat exchange apparatus of claim 1, wherein the vapor pipe and the gas outlet pipe are separate from each other, so that the vapor pipe is in communication with the plurality of gas outlet pipes via the gas-collecting groove.

9. The heat exchange apparatus of claim 1, wherein an end of the return pipe in communication with the evaporation section extends to a bottom of the evaporation section away from the condensation section, and an end of the vapor pipe in communication with the evaporation section is disposed at a top of the evaporation section adjacent to the condensation section.

10. The heat exchange apparatus of claim 1, wherein the gas-collecting hood further comprises a peripheral flange, which encircles a side of the first return wall facing the second return wall and, together with the first return wall, defines the gas-collecting groove.

11. The heat exchange apparatus of claim 10, wherein a peripheral side of the peripheral flange is provided with a plurality of protrusions distributed along a circumferential direction of the peripheral flange, adjacent two of the plurality of protrusions are disposed at intervals, and the peripheral flange is connected to an inner wall of the condensation section via the plurality of protrusions.

12. The heat exchange apparatus of claim 5, wherein when the evaporation section and the condensation section are disposed along the preset height direction, the first return wall is obliquely disposed relative to a plane perpendicular to the preset height direction, and the return gap is located at a lowest side of the first return wall along the preset height direction.

13. An inverter cooling system, comprising the heat exchanger apparatus of claim 1.

14. The inverter cooling system of claim 13, wherein the condensation section is provided with a plurality of vapor channels disposed at intervals, each of the plurality of vapor channels is in communication with corresponding one of the plurality of gas outlet pipes, the heat exchange apparatus further comprises an inner fin, and the inner fin is disposed in each of the plurality of vapor channels.

15. The inverter cooling system of claim 14, wherein the inner fin comprises a first condensing plate, a second condensing plate and a splitter plate, the splitter plate is connected to the first condensing plate and the second condensing plate, and the first condensing plate and the second condensing plate are disposed at intervals along a width direction of the plurality of gas outlet pipes and are disposed at two sides of the plurality of gas outlet pipes, respectively.

16. The inverter cooling system of claim 15, wherein the first condensing plate is provided with a plurality of first hollowed through-openings, the second condensing plate is provided with a plurality of second hollowed through-openings.

17. A converter cooling system, comprising the heat exchanger apparatus of claim 1.

18. The converter cooling system of claim 17, wherein the condensation section is provided with a plurality of vapor channels disposed at intervals, each of the plurality of vapor channels is in communication with corresponding one of the plurality of gas outlet pipes, the heat exchange apparatus further comprises an inner fin, and the inner fin is disposed in each of the plurality of vapor channels.

19. The converter cooling system of claim 18, wherein the inner fin comprises a first condensing plate, a second condensing plate and a splitter plate, the splitter plate is connected to the first condensing plate and the second condensing plate, and the first condensing plate and the second condensing plate are disposed at intervals along a width direction of the plurality of gas outlet pipes and are disposed at two sides of the plurality of gas outlet pipes, respectively.

20. The converter cooling system of claim 19, wherein the first condensing plate is provided with a plurality of first hollowed through-openings, the second condensing plate is provided with a plurality of second hollowed through-openings.
